(19) United States
(12) Patent Application Publication
(10) Pub. No.: US 2008/0116559 A1
(43) Pub. Date: May 22, 2008

(54) Semiconductor device, stacked semiconductor device and interposer substrate

(75) Inventors: Masayuki Hosono, Toshima-ku (JP); Akiji Shibata, Hitachi (JP); Kimio Inaba, Hitachi (JP)

Correspondence Address: FOLEY AND LARDNER LLP;SUITE 500, 3000 K STREET NW, WASHINGTON, DC, 20007, US

(73) Assignee: HITACHI CABLE, LTD

(21) Appl. No.: 11/979,785

(22) Filed: Nov. 8, 2007

(30) Foreign Application Priority Data
Nov. 17, 2006 (JP) 2006-311850

(51) Int. Cl. H01L 23/488

(52) U.S. Cl. 257/686; 257/738; 257/E23.023

(57) ABSTRACT

A semiconductor device has a semiconductor element; an interposer substrate having a wiring pattern electrically connected to the semiconductor element and an insulating substrate formed with the wiring pattern; a connection layer for adhering between the semiconductor element and the interposer substrate; and a solder ball external terminal arranged on the interposer substrate. The insulating substrate is folded in a portion mounted with the external terminal arranged on an outer side to the semiconductor element, and the unfolded and folded portions of the insulating substrate are opposite each other to form a gap therebetween.

The present application is based on Japanese Patent Application No. 2006-311850 filed on Nov. 17, 2006, the entire contents of which are incorporated herein by reference.

### BACKGROUND OF THE INVENTION

1. Field of the Invention

The present invention relates to a semiconductor device, a stacked semiconductor device, and an interposer substrate, and particularly, to a BAG-, CSP-, SIP-type semiconductor device, a composite semiconductor device thereof, a stacked semiconductor device, and an interposer substrate used in the semiconductor devices, in which stress acts between a semiconductor element and the interposer substrate, or between the interposer substrate and a printed wiring board (a motherboard).

2. Description of the Related Art

Conventionally, to relax stress caused between a semiconductor element and an interposer substrate of a semiconductor device, there are BAG-type semiconductor devices, etc. having a stress-relaxing elastomer between the semiconductor element and the interposer substrate.

This semiconductor device is characterized by including the stress-relaxing elastomer. As this stress-relaxing elastomer, known are an adhesive tape formed of a polymer material having not less than 1 MPa elastic modulus at solder reflow temperature (see JP-A-9-321084), or a porous resin tape formed of a continuous bubble structure or a three-dimensional reticulated structure (see JP-A-10-340968).

However, such a stress-relaxing elastomer is high in material cost, which is remarkable particularly in the porous resin tape formed of a continuous bubble structure or a three-dimensional reticulated structure as shown in JP-A-10-340968.

Accordingly, the following invention has been developed as an alternative to the stress-relaxing elastomer, and whose patent application (unpublished prior application) has been made first by the present applicants.

FIG. 1 is an explanatory diagram showing the structure of a semiconductor device with a specified connection layer, and FIG. 2 is an explanatory diagram showing the structure of the stacked semiconductor device.

A BAG-type semiconductor device 10 includes a connection layer 5 arranged between an interposer substrate 3 formed with a copper wiring pattern 2 on a polyimide insulating substrate (insulating tape) 1, and a semiconductor element 4 made of a Si chip, wherein these are caused to adhere to each other integrally.

The semiconductor device 10 includes an inner lead 6 in the wiring pattern 2 bonded to an electrode pad of the semiconductor element 4, using a specified bonding tool (not shown). The joining portion of the lead bonding and right-angle corner portion formed between the top surface of the connection layer 5 and the side surface of the semiconductor element 4 are sealed entirely with sealing resin 7 such as mold resin, potting resin, or the like. A solder ball 8 is mounted in via holes formed in the interposer substrate 3, and is electrically connected to a specified portion of the wiring pattern 2.

The connection layer 5 as an alternative to the stress-relaxing elastomer (herein, referred to as “elastomer alternative connection layer 5”) has layers constructed of materials or structure, which partially causes breakage, shear (slippage), or peeling, due to stress acting between the semiconductor element 4 and the interposer substrate 3 (the “stress” refers to thermal stress caused by a thermal expansivity difference between the semiconductor element and the package substrate, or stress due to an external shock acting on the solder ball 8 in the BGA package. Also, as breakage, there is fragile or ductile breakage, such as cracking, rupture, etc.

Breakage, shear (slippage), or peeling is caused partially in the adhesion interface between the semiconductor element 4 and the connection layer 5, the adhesion interface between the interposer substrate 3 and the connection layer 5, or the interface between the layers in the connection layer 5, but no separation is caused between the semiconductor element 4 and the interposer substrate 3. Where the semiconductor element 4 and the interposer substrate 3 are held with sealing resin 7 so as not to be separated from each other, breakage, shear (slippage), or peeling may be caused entirely as well as partially in the above adhesion interfaces.

Specifically, as shown in FIG. 1, for example, the connection layer 5 interposed between the semiconductor element 4 and the interposer substrate 3 is constructed to comprise a core layer 11 used as a support, and adhesive layers 12 and 13 for causing the core layer 11 to adhere to the semiconductor element 4 and the interposer substrate 3.

The core layer 11 is constructed of, for example, a dry film material comprising a filmed light curing material (photosensitive material) cured when exposed to light, a film material having mechanical structure having a liquid layer therein, etc. The connection layer 5 may be constructed of only the core layer 11 with adhesive strength of an adhesive caused to soak therethrough. Where a Ag paste material is used as the connection layer 5, the Ag paste material itself serves as the adhesive layer, and may therefore be used as the Ag paste material single layer. Namely, the connection layer 5 has a layer constructed of a tape (film) or paste, and may be used as mono-, bi-, tri-, tetra- or more-layer structure.

The adhesive layers 12 and 13 may be constructed of materials or have structure, which causes breakage, shear (slippage), or peeling in the adhesion interface to the core layer 11, to the semiconductor element 4, or to the interposer substrate 3, due to stress acting therein.

Although the above invention makes it possible to relax stress caused between the interposer substrate and the semiconductor element, it is, in addition thereto, important in structure design to relax stress caused by a thermal expansivity difference between the semiconductor package and the printed wiring board (motherboard) into which is incorporated the semiconductor package, or stress caused between stacked semiconductor devices, and there is a demand for a semiconductor device, a stacked semiconductor device, and an interposer substrate used in the semiconductor device, which have more excellent stress-relaxing capability.

### SUMMARY OF THE INVENTION

Accordingly, it is an object of the present invention to provide a semiconductor device, a stacked semiconductor device, and an interposer substrate used in the semiconductor device, which are excellent in relaxing stress caused between the interposer substrate and a printed wiring board (a motherboard), or stress caused between stacked semiconductor devices.
(1) In accordance with one embodiment of the invention, a semiconductor device comprises:

a semiconductor element;

an interposer substrate comprising a wiring pattern electrically connected to the semiconductor element and an insulating substrate formed with the wiring pattern;

a connection layer for adhering between the semiconductor element and the interposer substrate; and

a solder ball external terminal arranged on the interposer substrate,

wherein the insulating substrate is folded in a portion mounted with the external terminal arranged on an outer side to the semiconductor element, and the unfolded and folded portions of the insulating substrate are opposite each other to form a gap therebetween.
(2) In accordance with another embodiment of the invention, a semiconductor device comprises:

a semiconductor element;

an interposer substrate comprising a wiring pattern electrically connected to the semiconductor element and an insulating substrate formed with the wiring pattern;

a connection layer for adhering between the semiconductor element and the interposer substrate; and

a solder ball external terminal arranged on the interposer substrate,

wherein the insulating substrate is formed with a ramped portion that provides a step difference so that a portion mounted with the external terminal arranged on an outer side to the semiconductor element and a portion mounted with the semiconductor element are not coplanar.
(3) In accordance with another embodiment of the invention, a semiconductor device comprises:

a semiconductor element;

an interposer substrate comprising a wiring pattern electrically connected to the semiconductor element and an insulating substrate formed with the wiring pattern;

a connection layer for adhering between the semiconductor element and the interposer substrate; and

a solder ball external terminal arranged on the interposer substrate,

wherein the insulating substrate is formed with a slit on an outer side to a portion mounted with the semiconductor element.
(4) In accordance with another embodiment of the invention, a stacked semiconductor device comprises:

a plurality of semiconductor devices stacked with a solder ball external terminal, each semiconductor device comprising:

a semiconductor element;

an interposer substrate comprising a wiring pattern electrically connected to the semiconductor element and an insulating substrate formed with the wiring pattern;

a connection layer for adhering between the semiconductor element and the interposer substrate; and

the solder ball external terminal arranged on the interposer substrate,

wherein the insulating substrate is formed with a slit on an outer side to a portion mounted with the semiconductor element.
(5) In accordance with another embodiment of the invention, an interposer substrate comprises:

a wiring pattern electrically connected to a semiconductor element; and

an insulating substrate formed with the wiring pattern,

wherein the insulating substrate is folded in a portion mounted with a solder ball external terminal arranged on an outer side to the semiconductor element to be mounted, and the unfolded and folded portions of the insulating substrate are opposite each other to form a gap therebetween.
(6) In accordance with another embodiment of the invention, an interposer substrate comprises:

a wiring pattern electrically connected to a semiconductor element; and

an insulating substrate formed with the wiring pattern,

wherein the insulating substrate is formed with a ramped portion that provides 10 a step difference so that a portion mounted with the semiconductor element and a portion mounted with a solder ball external terminal arranged on an outer side to the semiconductor element to be mounted are not coplanar.
(7) In accordance with another embodiment of the invention, an interposer substrate comprises:

a wiring pattern electrically connected to a semiconductor element; and

an insulating substrate formed with the wiring pattern,

wherein the insulating substrate is formed with a slit on an outer side to a portion mounted with the semiconductor element.

### Advantages of the Invention

According to the present invention, it is possible to provide a semiconductor device, a stacked semiconductor device, and an interposer substrate used in the semiconductor device, which are excellent in relaxing stress caused between the interposer substrate and a printed wiring board (a motherboard), or stress caused between stacked semiconductor devices.

### BRIEF DESCRIPTION OF THE DRAWINGS

The preferred embodiments according to the invention will be explained below referring to the drawings, wherein:

FIG. 1 is an explanatory diagram showing the structure of a semiconductor device with an elastomer alternative connection layer;

FIG. 2 is an explanatory diagram showing the structure of a stacked semiconductor device with an elastomer alternative connection layer;

FIG. 3 is an explanatory diagram showing the structure of a semiconductor device in a first embodiment according to the present invention;

FIG. 4 is an explanatory diagram showing the structure of a stacked semiconductor device in the first embodiment according to the present invention;

FIG. 5 is an explanatory diagram showing the structure of a semiconductor device in a second embodiment according to the present invention;

FIG. 6 is an explanatory diagram showing the structure of a stacked semiconductor device in the second embodiment according to the present invention;

FIG. 7 is an explanatory diagram showing the structure of a semiconductor device in a third embodiment according to the present invention;

FIG. 8 is an explanatory diagram showing the structure of a stacked semiconductor device in the third embodiment according to the present invention;

FIG. 9 is an explanatory diagram showing the structure of a semiconductor device in a fourth embodiment according to the present invention;

FIG. 10 is an explanatory diagram showing the structure of a stacked semiconductor device in the fourth embodiment according to the present invention;

FIG. 11 is an explanatory diagram showing the structure of a semiconductor device in a fifth embodiment according to the present invention;

FIG. 12 is an explanatory diagram showing the structure of a stacked semiconductor device in the fifth embodiment according to the present invention;

FIG. 13 is an explanatory diagram showing the structure of a semiconductor device in a sixth embodiment according to the present invention;

FIG. 14 is an explanatory diagram showing the structure of a stacked semiconductor device in the sixth embodiment according to the present invention;

FIG. 15 is a diagram showing an example of slit shape formed in an insulating substrate in the semiconductor devices and the stacked semiconductor devices in the fifth and sixth embodiments according to the present invention;

FIG. 16 is a diagram showing an example of slit shape formed in an insulating substrate in the semiconductor devices and the stacked semiconductor devices in the fifth and sixth embodiments according to the present invention;

FIG. 17 is a diagram showing an example of slit shape formed in an insulating substrate in the semiconductor devices and the stacked semiconductor devices in the fifth and sixth embodiments according to the present invention; and

FIG. 18 is a diagram showing an example of slit shape formed in an insulating substrate in the semiconductor devices and the stacked semiconductor devices in the fifth and sixth embodiments according to the present invention.

### DETAILED DESCRIPTION OF THE PREFERRED EMBODIMENTS

### First Embodiment

Semiconductor Device Construction

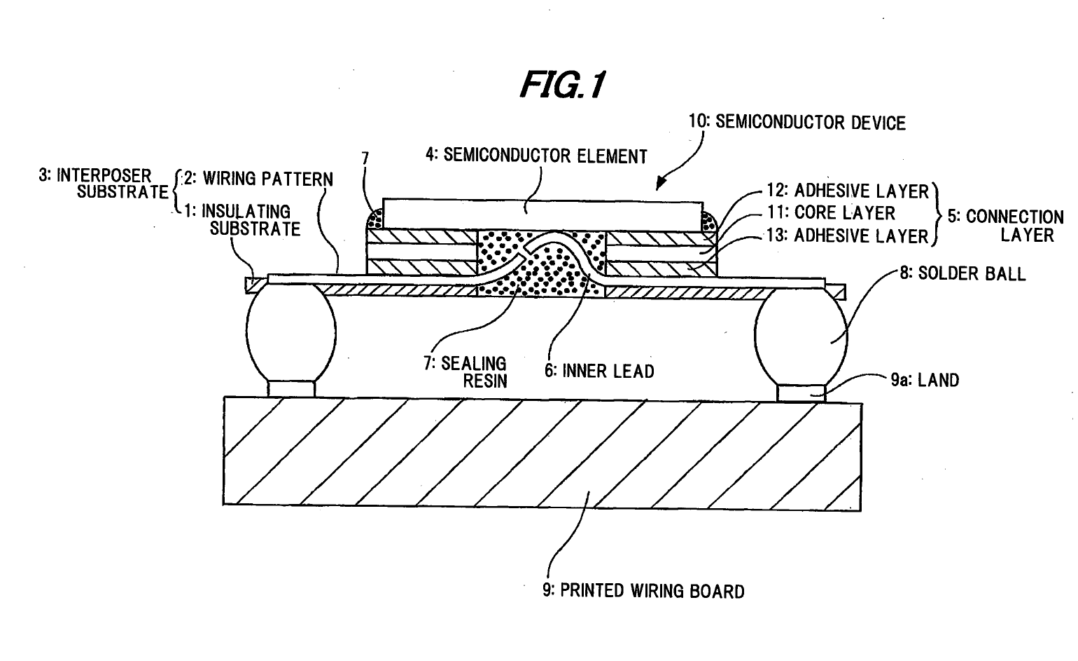

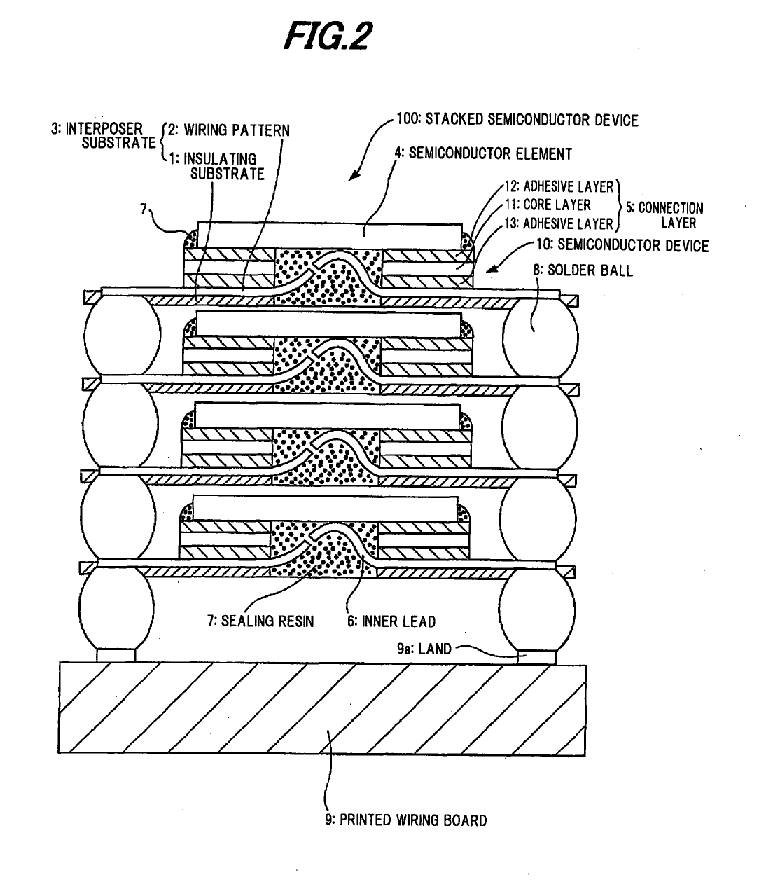

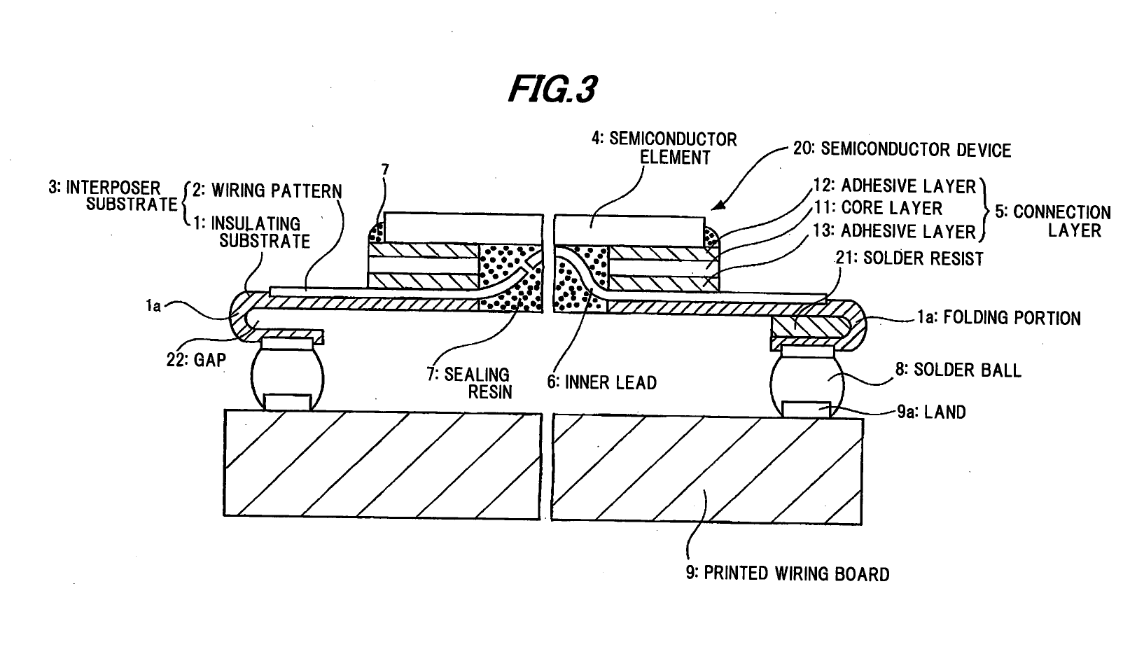

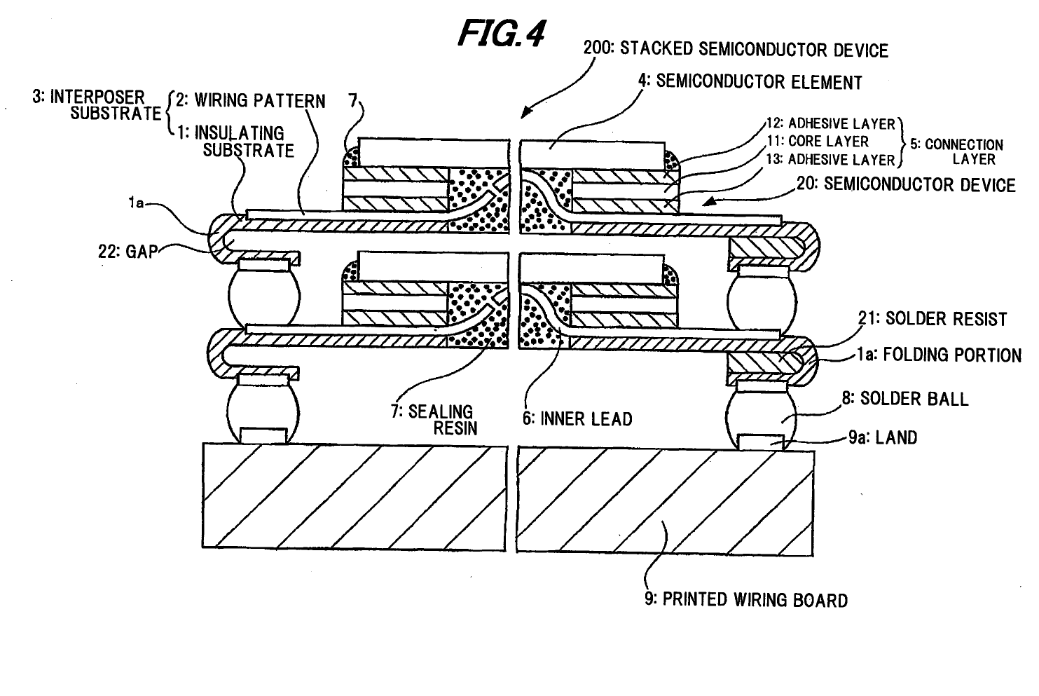

FIG. 3 is an explanatory diagram showing the structure of a semiconductor device in a first embodiment according to the present invention, and FIG. 4 is an explanatory diagram showing the structure of a stacked semiconductor device thereof. All but matters that will be explained below are the same as in the semiconductor device and the stacked semiconductor device shown in FIGS. 1 and 2, respectively. Further, the connection layer 5 is not limited to the elastomer alternative connection layer, but may use a conventional stress-relaxing elastomer. Also, only the adhesive layer may be used without providing the relaxing layer.

A BGA-type semiconductor device 20 includes a folding portion 1a formed by approximately 180°-folding solder ball 8 (solder ball 8 on outer sides to a semiconductor element 4)—mounting portions of an insulating substrate 1 constituting an interposer substrate 3, to a printed wiring board 9 side (a semiconductor element 4—unadhering side).

The unfolded and folded portions of the insulating substrate 1 are opposite each other so as to have a gap 22. This has the effects of being able to relax stress and of enhancement in space efficiency, and of size reduction of the solder balls 8.

The gap 22 is filled with solder resist, as shown in the right side of FIG. 3. As the filler, a stress-relaxing elastomer, an elastomer alternative connection layer, or the like may be used in place of the solder resist. This has advantageous effects in fixing the folding portion, dimension accuracy, and balancing.

This embodiment may, besides the (Fan-Out type) case where the solder balls 8 serving as external terminals are positioned on outer sides to the semiconductor element 4, as shown in FIG. 3, also apply to the (Fan-In/Out type) case where the solder balls 8 are positioned both below and on outer sides to the semiconductor element 4.

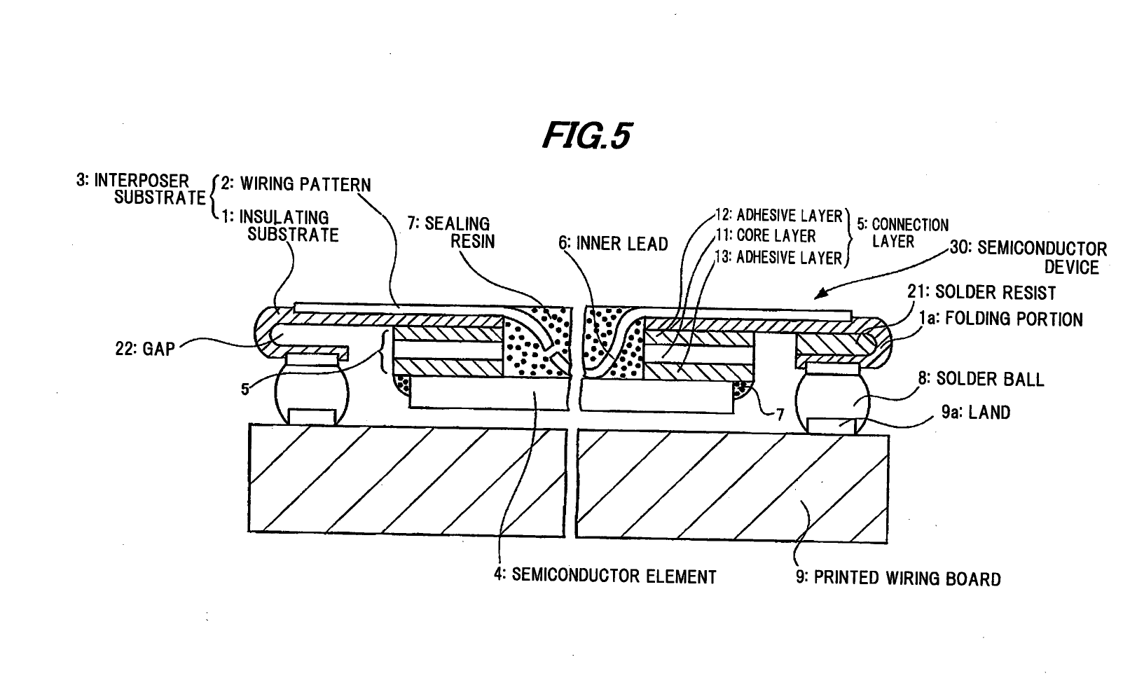

Further, in FIGS. 3 and 4, although not shown, a wiring pattern 2 is electrically connected to the solder balls 8 (The same applies to FIGS. 5-14 that are explanatory diagrams of second-sixth embodiments which will be explained later).

Advantages of the First Embodiment
(1) Since the folding portion 1a is provided in the solder ball-mounting portions of the insulating substrate 1, it is possible to relax stress caused between the semiconductor device 20 and the printed wiring board (motherboard) 9, and stress caused between semiconductor devices 20 of the stacked semiconductor device 200.
(2) It is possible to flexibly adjust the spacing between upper and lower semiconductor devices 20 during stacking the semiconductor devices 20. The solder balls, etc. can also be multi-pinned.

### Second Embodiment

Semiconductor Device Construction

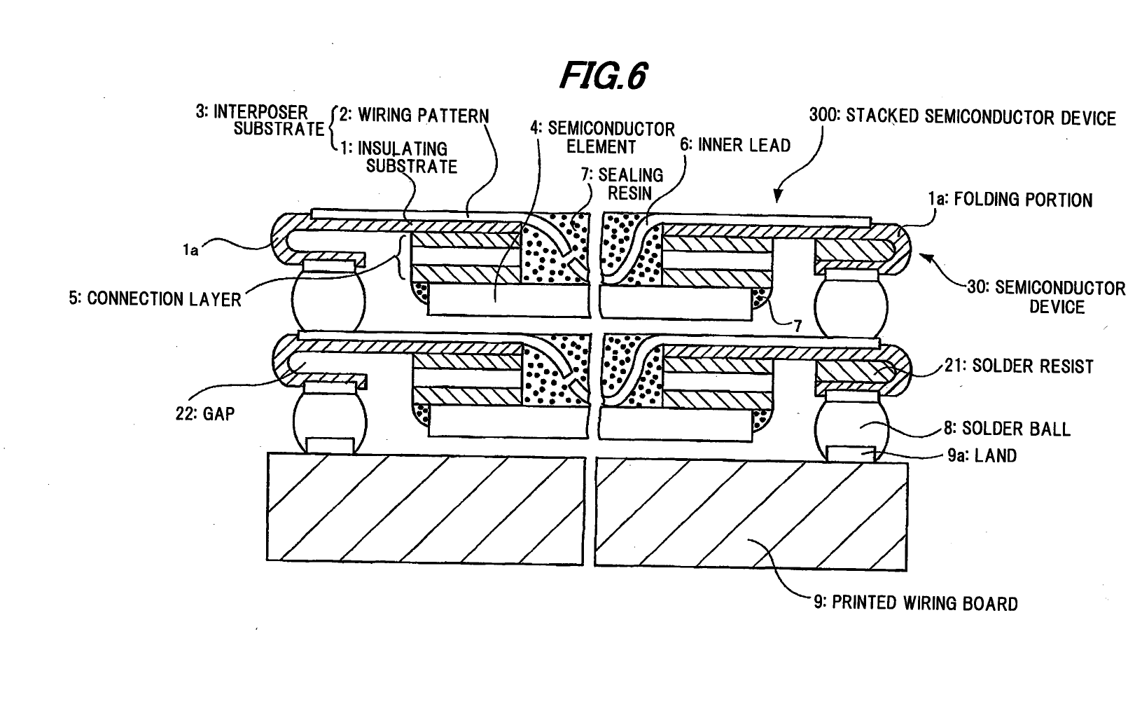

FIG. 5 is an explanatory diagram showing the structure of a semiconductor device in a second embodiment according to the present invention, and FIG. 6 is an explanatory diagram showing the structure of a stacked semiconductor device thereof. All but matters that will be explained below are the same as in the semiconductor device and the stacked semiconductor device in the first embodiment.

Namely, the difference is that while the semiconductor element 4 of the semiconductor device 20 in the first embodiment is caused to adhere to the side opposite the printed wiring board 9, the semiconductor element 4 of the semiconductor device 30 in the second embodiment is caused to adhere to the side facing the printed wiring board 9.

The folding portion 1a is formed by approximately 180°—folding solder ball 8 (solder ball 8 on outer sides to the semiconductor element 4)—mounting portions of the insulating substrate 1 constituting an interposer substrate 3, to the printed wiring board 9 side (the semiconductor element 4—adhering side).

This embodiment may apply to the (Fan-Out type) case where the solder balls 8 serving as external terminals are positioned on outer sides to the semiconductor element 4, as shown in FIG. 5.

### Third Embodiment

Semiconductor Device Construction

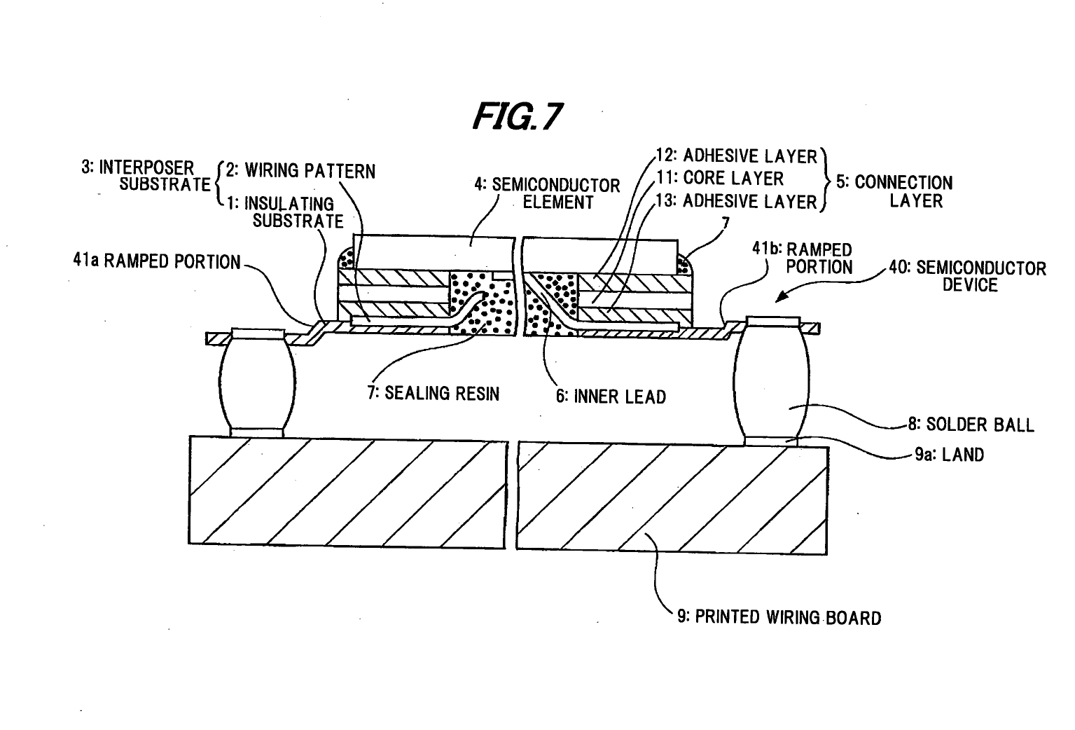

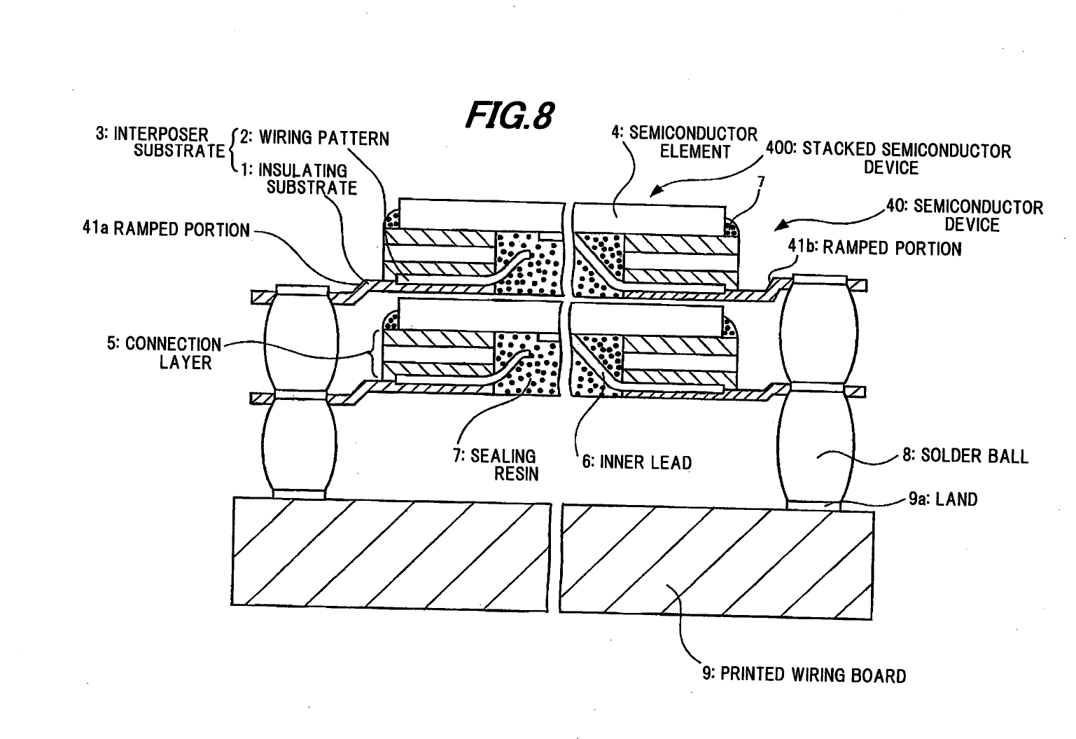

FIG. 7 is an explanatory diagram showing the structure of a semiconductor device in a third embodiment according to the present invention, and FIG. 8 is an explanatory diagram showing the structure of a stacked semiconductor device thereof. All but matters that will be explained below are the same as in the semiconductor device and the stacked semiconductor device shown in FIGS. 1 and 2, respectively. Further, the connection layer 5 is not limited to the elastomer alternative connection layer, but may use a conventional stress-relaxing elastomer. Also, only the adhesive layer may be used without providing the relaxing layer.

A BGA-type semiconductor device 40 has solder ball 8 (solder ball 8 on outer sides to a semiconductor element 4)—mounting portions in an insulating substrate 1 constituting an interposer substrate 3. The solder ball-mounting portions respectively have ramped portions 41a and 41b that are in a downward step (left side of FIG. 7) or upward step (right side of FIG. 7) shape to the semiconductor element 4—adhering (mounting) portion.

The solder ball-mounting portions and the semiconductor element 4—mounting portion only have to be not coplanar, and their level difference is desirably more than interposer substrate thickness and less than relevant package height.

This embodiment may, besides the (Fan-Out type) case where the solder balls 8 serving as external terminals are positioned on outer sides to the semiconductor element 4, as shown in FIG. 7, also apply to the (Fan-In/Out type) case where the solder balls 8 are positioned both below and on outer sides to the semiconductor element 4.

Advantages of the Third Embodiment
(1) Since the ramped portions 41a and 41b are provided such that the solder ball 8—mounting portions and the semiconductor element 4—mounting portion are in a step shape, it is possible to relax stress caused between the semiconductor device 40 and the printed wiring board (motherboard) 9, and stress caused between semiconductor devices 40 of the stacked semiconductor device 400.

### Fourth Embodiment

Semiconductor Device Construction

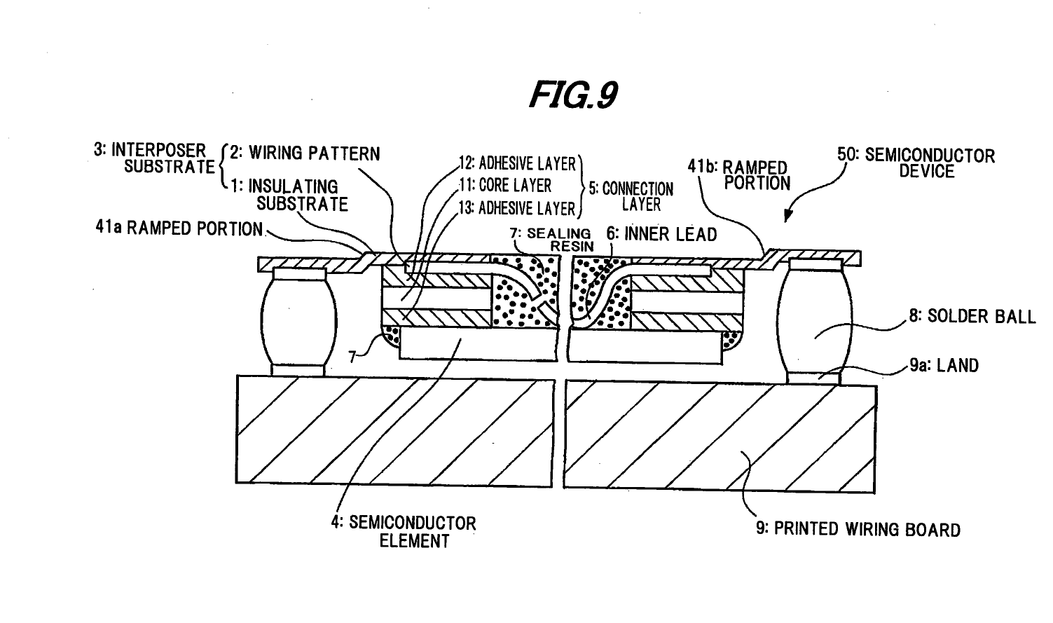

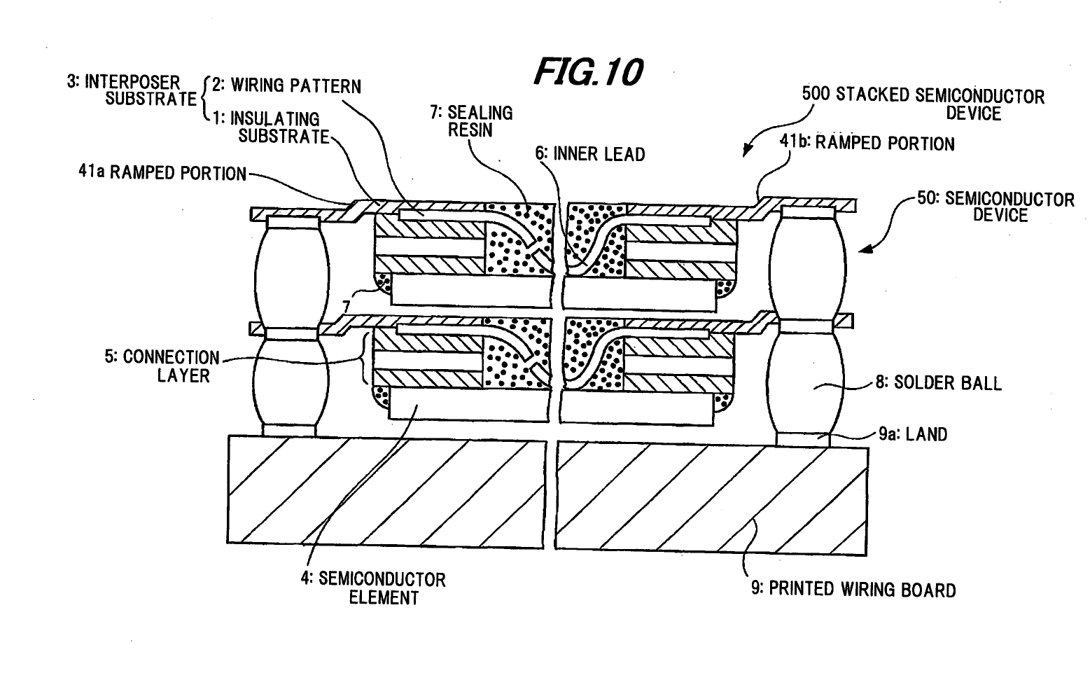

FIG. 9 is an explanatory diagram showing the structure of a semiconductor device in a fourth embodiment according to the present invention, and FIG. 10 is an explanatory diagram showing the structure of a stacked semiconductor device thereof. All but matters that will be explained below are the same as in the semiconductor device and the stacked semiconductor device in the third embodiment.

Namely, the difference is that while the semiconductor element 4 of the semiconductor device 40 in the third embodiment is caused to adhere to the side opposite the printed wiring board 9, the semiconductor element 4 of the semiconductor device 50 in the fourth embodiment is caused to adhere to the side facing the printed wiring board 9.

This embodiment may apply to the (Fan-Out type) case where the solder balls 8 serving as external terminals are positioned on outer sides to the semiconductor element 4, as shown in FIG. 9.

### Fifth Embodiment

Semiconductor Device Construction

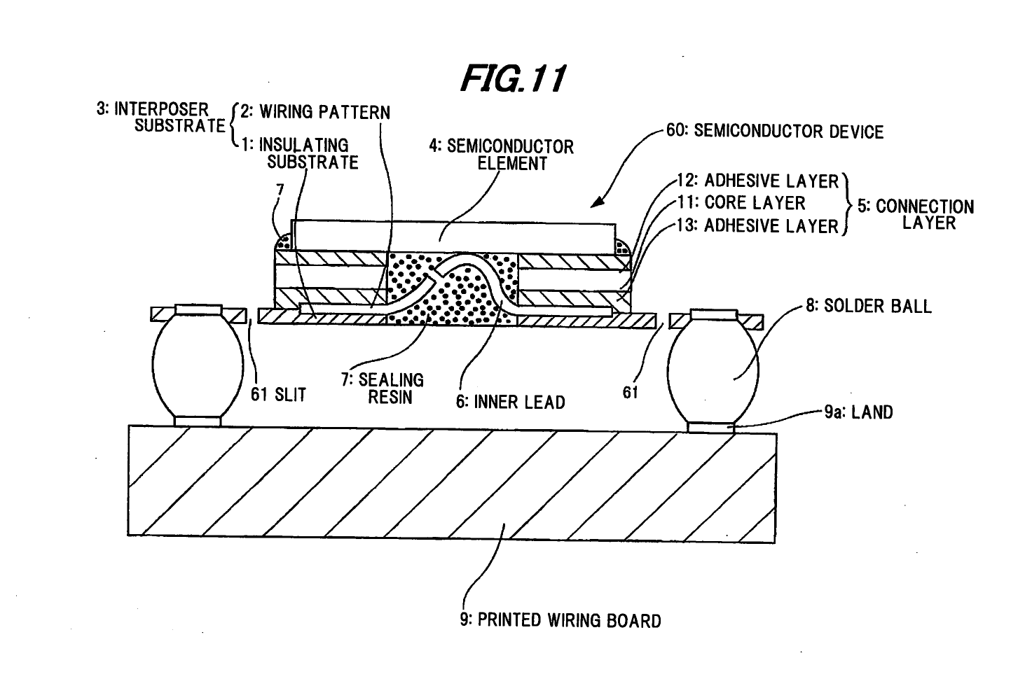

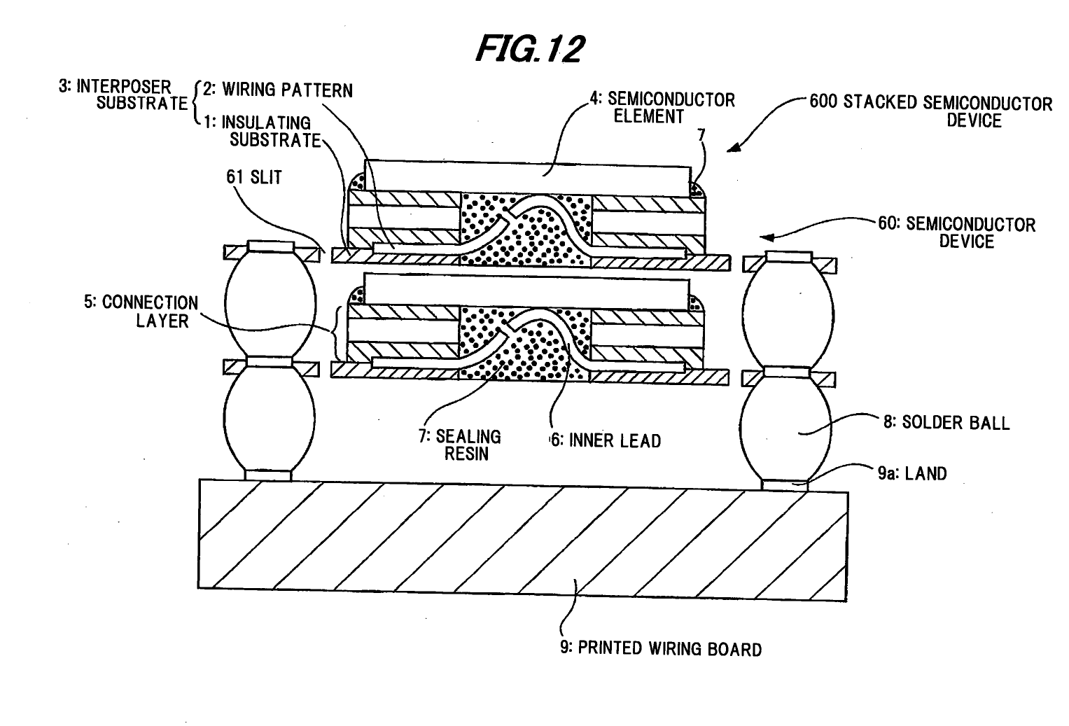

FIG. 11 is an explanatory diagram showing the structure of a semiconductor device in a fifth embodiment according to the present invention, and FIG. 12 is an explanatory diagram showing the structure of a stacked semiconductor device thereof. All but matters that will be explained below are the same as in the semiconductor device and the stacked semiconductor device shown in FIGS. 1 and 2, respectively. Further, the connection layer 5 is not limited to the elastomer alternative connection layer, but may use a conventional stress-relaxing elastomer. Also, only the adhesive layer may be used without providing the relaxing layer.

A BGA-type semiconductor device 60 has an insulating substrate 1 in which slits 61 are formed on outer sides to the semiconductor element 4—adhering (mounting) portion, for example, between the semiconductor element 4—mounting portion and the solder ball 8 (solder ball 8 on outer sides to the semiconductor element 4)—mounting portions, by punching, lasers, or the like. A wiring pattern 2 is designed to be arranged partially on the slits 61.

The slits 61 may be filled with buffer material, other plastic, or the like.

The slits 61 are desirably on the order of 1 μm-1 mm width, and on the order of 100 μm length—package entire length. The slit shape will be described in detail later.

This embodiment may, besides the (Fan-Out type) case where the solder balls 8 serving as external terminals are positioned on outer sides to the semiconductor element 4, as shown in FIG. 11, also apply to the (Fan-In/Out type) case where the solder balls 8 are positioned both below and on outer sides to the semiconductor element 4.

Advantages of the Fifth Embodiment
(1) Since the slits 61 are formed on outer sides to the semiconductor element 4—mounting portion (herein, between the semiconductor element 4—mounting portion and the solder ball 8—mounting portions, it is possible to relax stress caused between the semiconductor device 60 and the printed wiring board (motherboard) 9, and stress caused between semiconductor devices 40 of the stacked semiconductor device 600.

### Sixth Embodiment

Semiconductor Device Construction

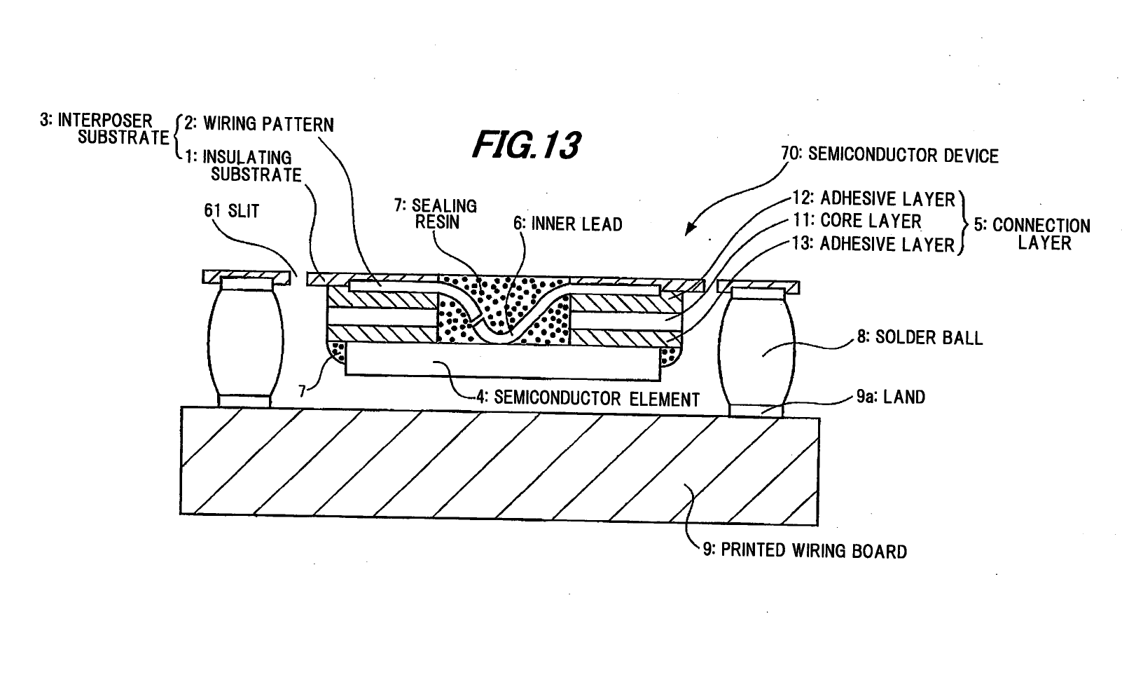

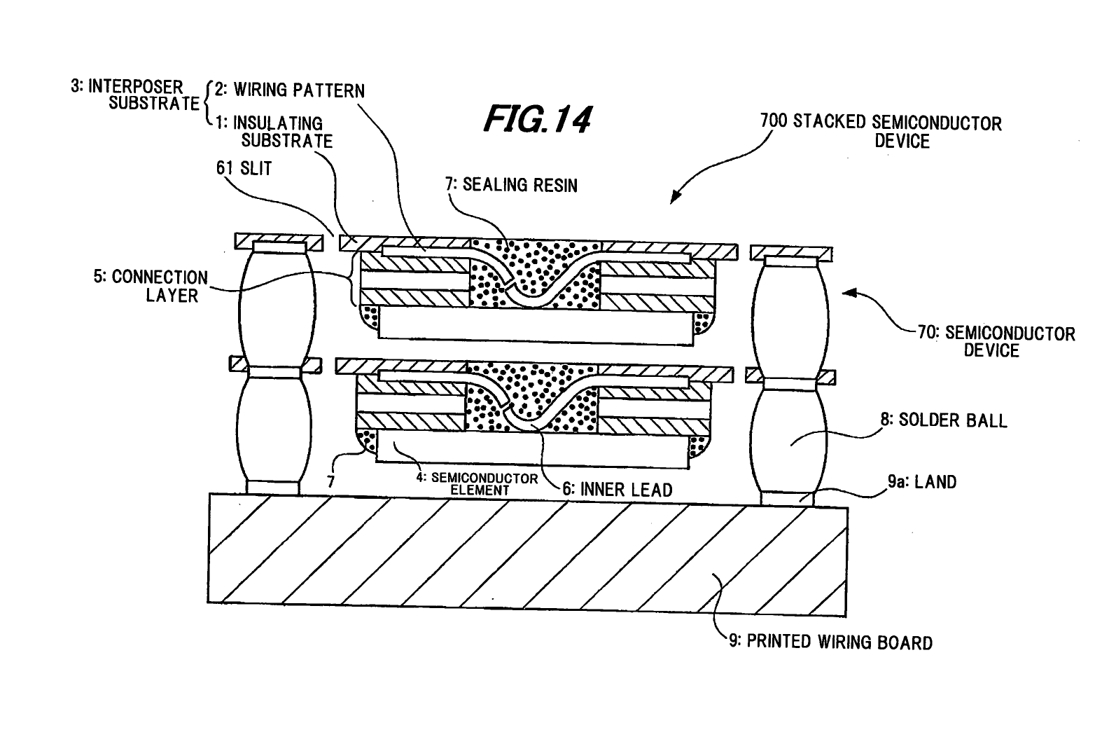

FIG. 13 is an explanatory diagram showing the structure of a semiconductor device in a sixth embodiment according to the present invention, and FIG. 14 is an explanatory diagram showing the structure of a stacked semiconductor device thereof. All but matters that will be explained below are the same as in the semiconductor device and the stacked semiconductor device in the fifth embodiment.

Namely, the difference is that while the semiconductor element 4 of the semiconductor device 60 in the fifth embodiment is caused to adhere to the side opposite the printed wiring board 9, the semiconductor element 4 of the semiconductor device 70 in the sixth embodiment is caused to adhere to the side facing the printed wiring board 9.

This embodiment may apply to the (Fan-Out type) case where the solder balls 8 serving as external terminals are positioned on outer sides to the semiconductor element 4, as shown in FIG. 13.

Slit Shape

In the semiconductor devices and the stacked semiconductor devices in the fifth and sixth embodiments according to the present invention, the slits 61 may be varied in shape, as explained below.

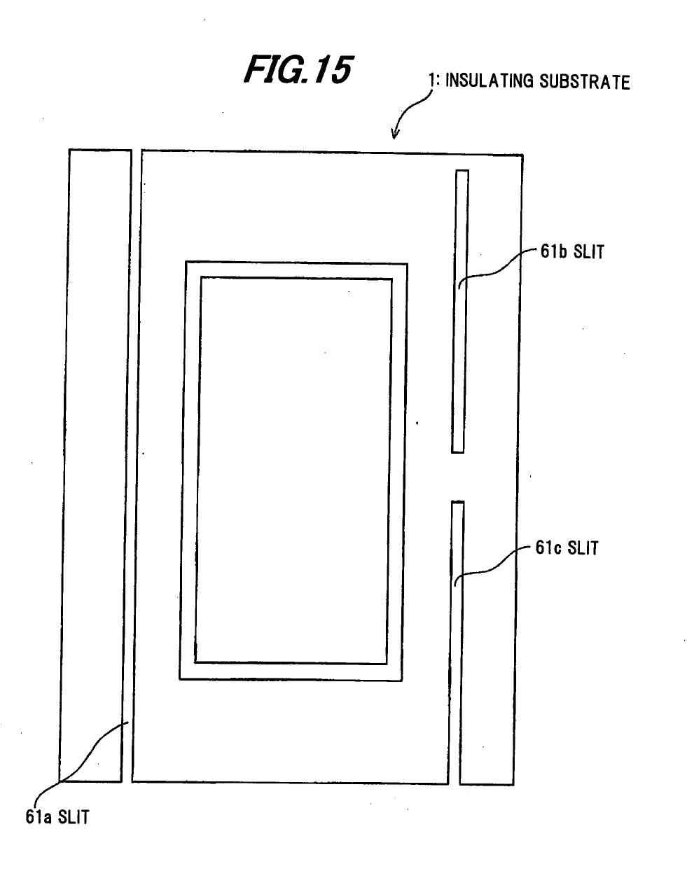

FIGS. 15-18 illustrate examples of slit 61 shape formed in the insulating substrate 1 in the semiconductor devices and the stacked semiconductor devices in the fifth and sixth embodiments according to the present invention.

A slit 61a in FIG. 15 completely separates the semiconductor element 4—mounting side and the solder ball 8 land/contact side, parallel to the long sides of the semiconductor element 4—mounting portion positioned in the middle of the figure. On the other hand, slits 61b and 61c incompletely separate the semiconductor element 4—mounting side and the solder ball 8 land/contact side, parallel to the long sides of the semiconductor element 4—mounting portion (the slit 61b is in a rectangular window shape, and the slit 61c is in a comb shape separated at one end).

Namely, the slits 61a-61c are formed parallel to the long sides of the semiconductor element 4—mounting portion positioned in the middle of the figure, to completely or partially separate the semiconductor element 4—mounting portion and the solder ball 8—mounting portions arranged on outer sides to the semiconductor element 4.

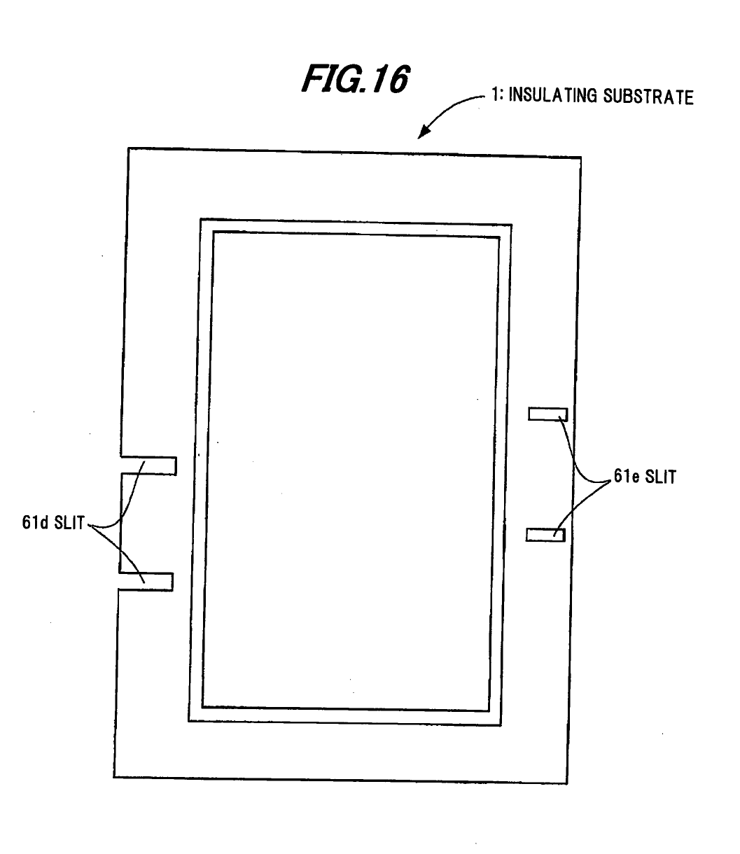

Slits 61d in FIG. 16 separate the solder ball 8 land/contact region in a comb shape, at right angles to the long (or short) sides of the semiconductor element 4—mounting portion positioned in the middle of the figure, and on an outer side to the semiconductor element 4. Also, slits 61e are in a rectangular window shape, to separate the solder ball 8 land/contact region, at right angles to the long (or short) sides of the semiconductor element 4—mounting portion, and on an outer side to the semiconductor element 4.

Namely, the slits 61d and 61e are formed perpendicularly to the long or short sides of the semiconductor element 4—mounting portion positioned in the middle of the figure, to completely or partially separate the semiconductor element 4—mounting portion and the solder ball 8—mounting portions arranged on outer sides to the semiconductor element 4.

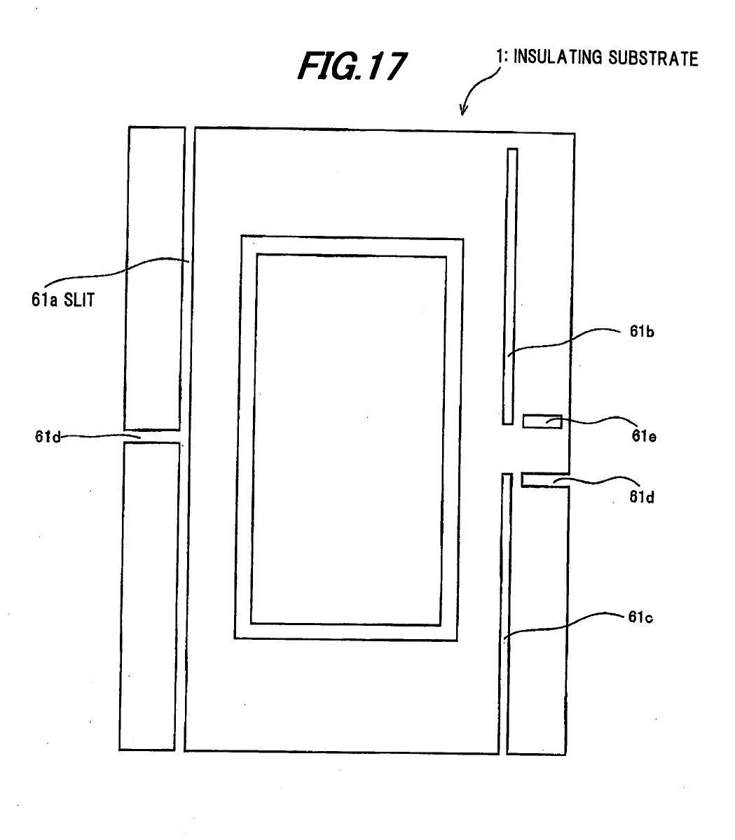

FIG. 17 illustrates a composite form having all of the slits 61a-61e shown in FIGS. 15 and 16.

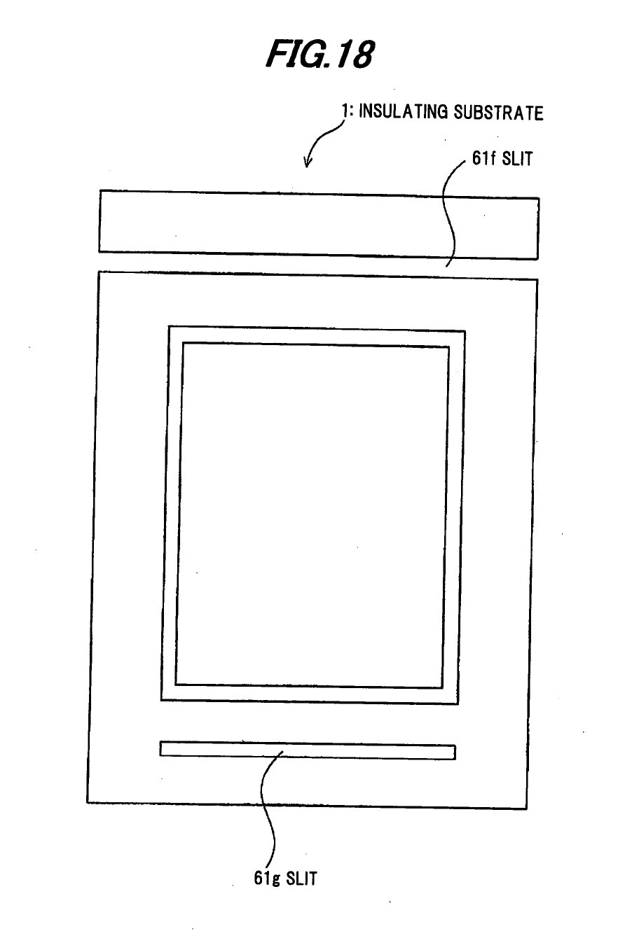

A slit 61f in FIG. 18 completely separates the semiconductor element 4—mounting side and the solder ball 8 land/contact side, parallel to the short sides of the semiconductor element 4—mounting portion positioned in the middle of the figure. On the other hand, a slit 61g incompletely separate the semiconductor element 4—mounting side and the solder ball 8 land/contact side, parallel to the short sides of the semiconductor element 4—mounting portion (the slit 61g is in a rectangular window shape).

Namely, the slits 61f and 61g are formed parallel to the short sides of the semiconductor element 4—mounting portion positioned in the middle of the figure, to completely or partially separate the semiconductor element 4—mounting portion and the solder ball 8—mounting portions arranged on outer sides to the semiconductor element 4.

Form of Elastomer Alternative Connection Layer 5

Although the above explanation is duplicated partially, the possible forms of the elastomer alternative connection layer 5 are as follows.
(1) The connection layer 5 has layers constructed of materials or structure, which partially causes breakage, shear (slippage), or peeling in the adhesion interface between the semiconductor element 4 and the connection layer 5, the adhesion interface between the interposer substrate 3 and the connection layer 5, or the interface between the layers in the connection layer 5, due to stress acting between the semiconductor element 4 and the interposer substrate 3.
(2) The connection layer 5 has layers constructed of materials or structure, which partially causes breakage or shear (slippage) in the connection layer 5, but no separation between the semiconductor element 4 and the interposer substrate 3, due to stress acting between the semiconductor element 4 and the interposer substrate 3.
(3) The semiconductor element 4 and the interposer substrate 3 are held with resin partially or entirely so as not to be separated from each other, and the connection layer 5 has layers constructed of materials or structure, which causes breakage, shear (slippage), or peeling in the adhesion interface between the semiconductor element 4 and the connection layer 5, the adhesion interface between the interposer substrate 3 and the connection layer 5, or the interface between the layers in the connection layer 5, due to stress acting between the semiconductor element 4 and the interposer substrate 3.
(4) The semiconductor element 4 and the interposer substrate 3 are held with resin partially or entirely so as not to be separated from each other, and the connection layer 5 has layers constructed of materials or structure, which causes breakage or shear (slippage) in the connection layer 5, due to stress acting between the semiconductor element 4 and the interposer substrate 3.
(5) The connection layer 5 has layers constructed of a tape (film) or paste.
(6) The connection layer 5 is constructed to comprise a core layer 11, and adhesive layers 12 and 13 for causing the core layer 11 to adhere to the semiconductor element 4 and the interposer substrate 3.
(7) The connection layer 5 is constructed from monolayer or bilayer adhesive layers.
(8) The connection layer 5 is constructed from a bi- or more-layer adhesive core layer.
(9) The connection layer 5 has layers constructed of a dry film material comprising a filmed light curing material (photosensitive material), a film material having mechanical structure having a liquid layer therein, or a Ag paste material.

The possible forms of the elastomer alternative connection layer 5 are explained below more specifically.

Monolayer Connection Layer

The connection layer 5 is constructed from a monolayer film base material and an adhesive caused to soak therethrough. The adhesive strength of the adhesive to the semiconductor element 4 or the interposer substrate 3 is as relatively weak as between 1-500 gf (0.01-5 N)/mm², to cause shear (slippage) or peeling between the adhering mates, to absorb stress thereof.

Monolayer Connection Layer

The connection layer 5 is constructed from a paste comprising a resin material and a filling material such as fillers. The paste is used that partially or totally causes peeling in the interface between the resin material and the filling material, or cracking, breakage, etc. in the resin material (bulk), at a stress of 0.01-5 N/mm² or more, to absorb the stress.

Bilayer Connection Layer

The connection layer 5 has a bilayer structure formed by superimposing two above-mentioned adhesive-soaked monolayer film base materials. The adhesive strength of the adhesive to the semiconductor element 4 or the interposer substrate 3 is as relatively weak as between 0.01-5 N/mm², to cause shear (slippage) or peeling between the adhering mates, or between the two film base material layers, to absorb stress thereof.

Bilayer Connection Layer

The connection layer 5 has a bilayer structure formed by superimposing two film base materials of the above-mentioned adhesive-soaked monolayer film base material and a film base material with an adhesive strength different from that of the monolayer film base material. The adhesive strength of the adhesive to the semiconductor element 4 or the interposer substrate 3 is as relatively weak as between 0.01-5 N/mm², to cause shear (slippage) or peeling between the adhering mates, or between the two film base material layers, to absorb stress thereof.

Trilayer Connection Layer

The connection layer 5 has a trilayer structure formed by superimposing 3 above-mentioned adhesive-soaked monolayer film base materials or two above-mentioned adhesive-soaked monolayer film base materials and one film base material with an adhesive strength different from that of the monolayer film base material, (regardless of order). The adhesive strength of the adhesive to the semiconductor element 4 or the interposer substrate 3 is as relatively weak as between 0.01-5 N/mm², to cause shear (slippage) or peeling between the adhering mates, or between the same or different film base materials, to absorb stress thereof.

Bilayer Connection Layer (an Example of Connection Layer Directionality)

The connection layer 5 has a bilayer structure formed by superimposing two above-mentioned adhesive-soaked monolayer film base materials (core layers 11A and 11B) or one above-mentioned adhesive-soaked monolayer film base material and one film base material with an adhesive strength different from that of the monolayer film base material (the adhesive strength of the adhesive to the semiconductor element 4 or the interposer substrate 3 is as relatively weak as between 0.01-5 N/mm²), and each layer has directionality in peeling or cleavage strength (e.g., strong in an X direction, and weak in a Y direction). For example, 2 same film base materials shifted by 90 degrees are superposed to intentionally cause peeling, cleavage, etc. of each layer, to absorb every stress from the XY plane, 360 degrees that acts on the semiconductor element 4. Further, the direction shift of 2 upper and lower adhesive layers is in the range of 45-135 degrees.

Tri- or More-Layer Connection Layer (an Example of Being Absorbed by the Core Layer)

The connection layer 5 has a trilayer structure formed by superimposing three or more above-mentioned adhesive-soaked monolayer film base materials (core layers 11A and 11B) or two above-mentioned adhesive-soaked monolayer film base material and one or more film base materials with an adhesive strength different from that of the monolayer film base material (the adhesive strength of the adhesive to the semiconductor element 4 or the interposer substrate 3 is as relatively weak as between 0.01-5 N/mm²), and each layer has directionality in peeling or cleavage strength (e.g., strong in an X direction, and weak in a Y direction). For example, 2 same film base materials (core layer 11A) shifted by 90 degrees are superposed, and 2 same film base materials (core layer 11B) shifted by 90 degrees, different from the core layer 11A, are superposed to sandwich the 2 superposed film base materials (core layer 11A) therebetween, to cause peeling, cleavage, etc. of each layer, and thereby absorb every stress from the XY plane, 360 degrees that acts on the semiconductor element 4. Further, the direction shift of 2 same upper and lower adhesive layers is in the range of 45-135 degrees.

In the above specific examples, although the adhesive is caused to soak through the core layers, an adhesive layer may be provided on one side or both sides separately.

Adhesive Strength Adjustment

Examples of methods for adjusting the adhesive strength of the connection layer 5 are given below.
(1) The amount of the paste base material is reduced to increase the proportion of portion of the filler, etc. that does not affect the adhesion directly, to thereby reduce the adhesion area to the adhering mate in the connection layer, so that the adhesive strength can be controlled to be low.
(2) The adhesive is caused to soak in patches (inhomogeneously), so that variation (0-100%) in the adhesive strength can be realized.
(3) The adhesive is caused to soak partially, to reduce the adhesion area to the adhering mate in the connection layer, so that the adhesive strength can be controlled to be low.
(4) In the case of a bi- or more-layer core layer, the adhesive caused to soak is altered for each layer, to adjust the adhesive strength between the adhesive layers to be lower than the adhesive strength of the adhesive layers to the adhering mate, so that shear (slippage) or peeling can be caused first between the adhesive layers.

Advantages of Elastomer Alternative Connection Layer 5

According to the embodiments using the elastomer alternative connection layer 5, the following advantages are exhibited.
(1) By using the connection layer constructed of materials or having structure which causes breakage, shear (slippage), or peeling when stress acts between the semiconductor element and the interposer substrate, it is possible to provide the semiconductor device that can relax that stress. Here, the relax refers to absorption, dispersion, etc.
(2) Because no conventional stress-relaxing elastomer is used, it is possible to reduce material cost in constructing the semiconductor device and the interposer substrate, and also handling thereof is easy compared with the conventional stress-relaxing elastomer.

### Other Embodiments

The present invention is not limited to each above embodiment, but various modifications can be made within the scope not deviating from or altering the technical ideas of the present invention.

For example, although the above embodiments have been explained by way of the examples of the BGA-type semiconductor devices, they may also be applied to semiconductor devices, that cause the same problem, such as CSP- or SIP-type semiconductor devices, or MCPs (multi-chip packages).

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor element;
an interposer substrate comprising a wiring pattern electrically connected to the semiconductor element and an insulating substrate formed with the wiring pattern;
a connection layer for adhering between the semiconductor element and the interposer substrate; and
a solder ball external terminal arranged on the interposer substrate,
wherein the insulating substrate is folded in a portion mounted with the external terminal arranged on an outer side to the semiconductor element, and the unfolded and folded portions of the insulating substrate are opposite each other to form a gap therebetween.

2. The semiconductor device according to claim 1, wherein:
the gap is filled with a solder resist, a stress-relaxing elastomer, or an elastomer alternative connection layer.

3. A semiconductor device, comprising:
a semiconductor element;
an interposer substrate comprising a wiring pattern electrically connected to the semiconductor element and an insulating substrate formed with the wiring pattern;
a connection layer for adhering between the semiconductor element and the interposer substrate; and
a solder ball external terminal arranged on the interposer substrate,
wherein the insulating substrate is formed with a ramped portion that provides a step difference so that a portion mounted with the external terminal arranged on an outer side to the semiconductor element and a portion mounted with the semiconductor element are not coplanar.

4. The semiconductor device according to claim 1, wherein:
the connection layer comprises a stress-relaxing elastomer connection layer or an elastomer alternative connection layer.

5. The semiconductor device according to claim 1, wherein:
the semiconductor device is a BAG-type, CSP- or SIP-type semiconductor device, or a composite (MCP: multi-chip package) semiconductor device thereof.

6. The semiconductor device according to claim 1, wherein:
a plurality of the semiconductor devices are stacked with the solder ball external terminal.

7. The semiconductor device according to claim 3, wherein:
the connection layer comprises a stress-relaxing elastomer connection layer or an elastomer alternative connection layer.

8. The semiconductor device according to claim 3, wherein:
the semiconductor device is a BAG-type, CSP- or SIP-type semiconductor device, or a composite (MCP: multi-chip package) semiconductor device thereof.

9. The semiconductor device according to claim 3, wherein:
a plurality of the semiconductor devices are stacked with the solder ball external terminal.

10. An interposer substrate, comprising:
a wiring pattern electrically connected to a semiconductor element; and
an insulating substrate formed with the wiring pattern,
wherein the insulating substrate is folded in a portion mounted with a solder ball external terminal arranged on an outer side to the semiconductor element to be mounted, and the unfolded and folded portions of the insulating substrate are opposite each other to form a gap therebetween.

11. An interposer substrate, comprising:
a wiring pattern electrically connected to a semiconductor element; and
an insulating substrate formed with the wiring pattern,
wherein the insulating substrate is formed with a ramped portion that provides a step difference so that a portion mounted with the semiconductor element and a portion mounted with a solder ball external terminal arranged on an outer side to the semiconductor element to be mounted are not coplanar.
